(19) United States
(12) Patent Application Publication
(10) Pub. No.: US 2024/0355874 A1
(43) Pub. Date: Oct. 24, 2024

(54) SEMICONDUCTOR APPARATUS, POWER CONVERTER AND MANUFACTURING METHOD FOR SEMICONDUCTOR APPARATUS

(71) Applicant: Mitsubishi Electric Corporation, Tokyo (JP)

(72) Inventors: Atsufumi INOUE, Tokyo (JP); Tetsu NEGISHI, Tokyo (JP); Tsuyoshi KAWAKAMI, Tokyo (JP); Tomohiro TAMAKI, Tokyo (JP)

(73) Assignee: Mitsubishi Electric Corporation, Tokyo (JP)

(21) Appl. No.: 18/685,521

(22) PCT Filed: Oct. 14, 2021
(86) PCT No.: PCT/JP2021/038065

§ 371 Date: Feb. 22, 2024

(51) Int. Cl. H01L 29/06; H01L 21/02; H01L 21/285; H01L 21/3205; H01L 23/36; H01L 29/16; H01L 29/20; H01L 29/24; H01L 29/739; H01L 29/78

(52) U.S. Cl. CPC H01L 29/0653; H01L 21/02118; H01L 21/02345; H01L 21/32051; H01L 23/36; H01L 21/28506; H01L 29/1608; H01L 29/2003; H01L 29/24; H01L 29/7395; H01L 29/7827

(57) ABSTRACT

A semiconductor apparatus includes: a semiconductor substrate; a first surface electrode on the substrate and a second surface electrode formed separately and insulated from the first surface electrode; an electroconductive layer formed between the electrodes with a space from the electrodes; an insulating layer formed to cover the electroconductive layer, a surface between the electrodes, and an end portion of each electrode on a side close to the electroconductive layer; a short-circuit prevention layer having an insulating property formed to cover the insulating layer between the electrodes and the electroconductive layer, the short-circuit prevention layer having a thickness equal to or larger than a height of the electroconductive layer and being made of a material different from that of the insulating layer; a metal plating layer formed on the electrodes; and a reverse-surface electrode on the opposite surface of the substrate, thereby being capable of preventing the electrodes from short-circuiting.

### TECHNICAL FIELD

The present disclosure relates to a semiconductor apparatus and a manufacturing method for the semiconductor apparatus, and a power converter with it.

### BACKGROUND ART

A semiconductor apparatus used for power control of automobile equipment, industrial equipment, etc., is composed of switching devices such as an insulated gate bipolar transistor (IGBT) and an insulated gate field effect transistor (MOSFET: metal oxide semiconductor field effect transistor), diodes, and the like. A semiconductor substrate used for such a semiconductor apparatus is thinned due to the need to suppress conduction loss, turn-off loss, etc.

In a thinned semiconductor substrate, both the heat capacity and the heat dissipation properties decrease. Therefore, in the case of IGBTs, for example, the time during which the IGBTs are not destroyed, even if they are operated in ON state while in a short-circuit state, may decrease, i.e., the short-circuit capacity may decrease. Meanwhile, the semiconductor apparatus is required to improve the heat dissipation properties of the semiconductor substrate for the case where it is used in high temperature environment or for the case where the current to be controlled and the heat generation increase.

Previously, a power semiconductor apparatus has been known which forms a metal layer on the surface of a semiconductor device by a plating method to facilitate heat dissipation. Patent Document 1 discloses a technique for forming a metal layer containing nickel on a surface electrode of a semiconductor device by an electroless plating method and to causing heat to be dissipated from the surface of the semiconductor device through the metal layer.

### PRIOR ART DOCUMENTS

### Patent Documents

[Patent Document 1] Japanese Patent No. 5494559 (see pages 3 to 4, etc.)

### SUMMARY OF THE INVENTION

### Problems to be Solved by the Invention

For example, a gate electrode and an emitter electrode, gate wiring to be provided on a wiring region between the gate electrode and the emitter electrode, and an insulating film covering the gate wiring are formed on the surface of the semiconductor device. In the semiconductor device having the electrodes insulated from each other, an electroconductive layer formed in a region between the electrodes with a space from the electrodes, and an insulating layer covering the electroconductive layer as described above, an uneven structure is formed. When a metal plating layer is formed on each of the electrodes insulated from each other, substances contained in plate processing solutions, such as a plating solution and a plating solution detergent, sometimes remain on the surface of the insulating layer covering the electroconductive layer, especially in recesses between the electrodes and the electroconductive layer, and form an electroconductive coating, thus short-circuiting between the electrodes insulated from each other.

The object of the present disclosure is to solve the above problem and to provide a semiconductor apparatus in which the short-circuiting between the electrodes is prevented when a metal plating layer is formed on each of the electrodes insulated from each other on the surface of the semiconductor device.

### Means for Solving Problem

A semiconductor apparatus according to the present disclosure includes: a semiconductor substrate having a first main surface and a second main surface which is an opposite surface to the first main surface; a first surface electrode formed on the first main surface; a second surface electrode formed separately from the first surface electrode in a planar view and electrically insulated from the first surface electrode; an electroconductive layer having an electroconductive property formed on the first main surface between the first surface electrode and the second surface electrode with a space from the first surface electrode and the second surface electrode in a planar view; an insulating layer having an insulating property formed to cover the electroconductive layer, the first main surface between the first surface electrode and the second surface electrode, and an end portion of each of the first surface electrode and the second surface electrode on a side close to the electroconductive layer; a short-circuit prevention layer having an insulating property formed to cover the insulating layer between the first surface electrode and the electroconductive layer and the insulating layer between the second surface electrode and the electroconductive layer, the short-circuit prevention layer having a thickness equal to or larger than a height from a lower end to an upper end of the electroconductive layer and being made of a material different from that of the insulating layer; a metal plating layer formed on each of the first surface electrode and the second surface electrode; and a reverse-surface electrode formed on the second main surface.

A manufacturing method for a semiconductor apparatus according to the present disclosure includes: a surface-electrode and electroconductive-layer formation step of forming a first surface electrode, a second surface electrode and the electroconductive layer with a space from each other in a planar view by forming and patterning a planar electrode layer on a first main surface of a semiconductor substrate; an insulating layer formation step of forming the electroconductive layer, the first main surface between the first surface electrode and the second surface electrode, and the insulating layer covering an end portion of each of the first surface electrode and the second surface electrode on a side close to the electroconductive layer using a PVD or CVD method; a short-circuit prevention layer formation step of forming a short-circuit prevention layer having an insulating property, the short-circuit prevention layer covering the insulating layer between the first surface electrode and the electroconductive layer and the insulating layer between the second surface electrode and the electroconductive layer, having a thickness equal to or larger than a height from a lower end to an upper end of the electroconductive layer, and being made of a material different from that of the insulating layer; a metal plating layer formation step, following the short-circuit prevention layer formation step, of forming a metal plating layer on the first surface electrode and on the second surface electrode using a plating method by immersing the first surface electrode, the second surface electrode and the short-circuit prevention layer in a plate processing solution; and a reverse-surface electrode formation step of forming a reverse-surface electrode on a second main surface which is an opposite surface to the first main surface of the semiconductor substrate.

### Effects of the Invention

According to the present disclosure, a semiconductor apparatus capable of preventing the short-circuiting between electrodes is obtained by forming a short-circuit prevention layer between the electrodes insulated from each other on the surface of the semiconductor device.

### BRIEF DESCRIPTION OF THE DRAWINGS

FIG. 1 is a planar schematic diagram showing a schematic configuration of a semiconductor apparatus according to Embodiment 1.

FIG. 2 is a cross-sectional schematic diagram showing a schematic configuration of the semiconductor apparatus according to Embodiment 1.

FIG. 3 is a cross-sectional schematic diagram showing a schematic configuration of the semiconductor apparatus according to Embodiment 1.

FIG. 4 is a cross-sectional schematic diagram showing a schematic configuration of the semiconductor apparatus according to Embodiment 1.

FIG. 5 is a cross-sectional schematic diagram showing a schematic configuration of a semiconductor apparatus according to Embodiment 2.

FIG. 6 is a graph showing short-circuit capacity of the semiconductor apparatus according to Embodiment 2.

FIG. 7 is a planar schematic diagram showing a schematic configuration of the semiconductor apparatuses according to Embodiment 1 or 2.

FIG. 8 is a schematic diagram showing a schematic configuration of a power conversion system to which a power converter according to Embodiment 3 is applied.

### EMBODIMENTS FOR CARRYING OUT THE INVENTION

Embodiments in the present disclosure will be described in detail below with reference to the drawings. IGBTs are used as examples in the description. However, the semiconductor apparatus can be changed as appropriate as long as it includes the electrodes insulated from each other on the surface of the semiconductor device, the electroconductive layer formed in the region between the electrodes with a space from the electrodes in a planar view, and the insulating layer covering the electroconductive layer. Also, instead of IGBTs, MOSFETs or switching devices equivalent to IGBTs and MOSFETs can be used for the semiconductor apparatus.

### Embodiment 1

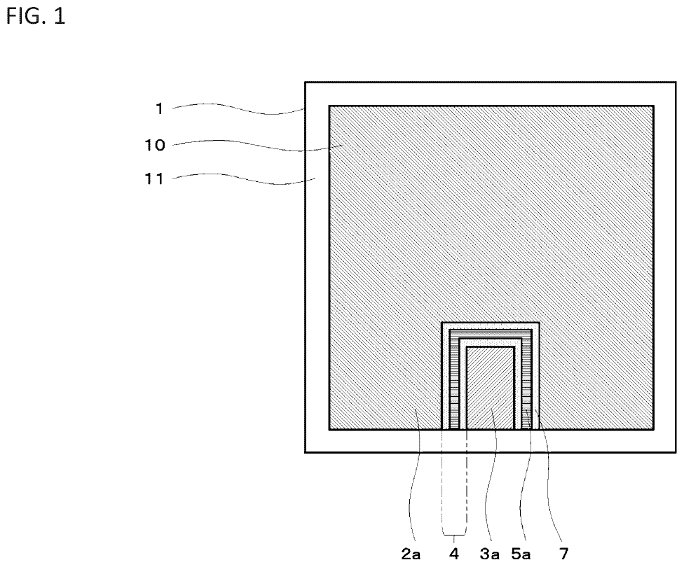

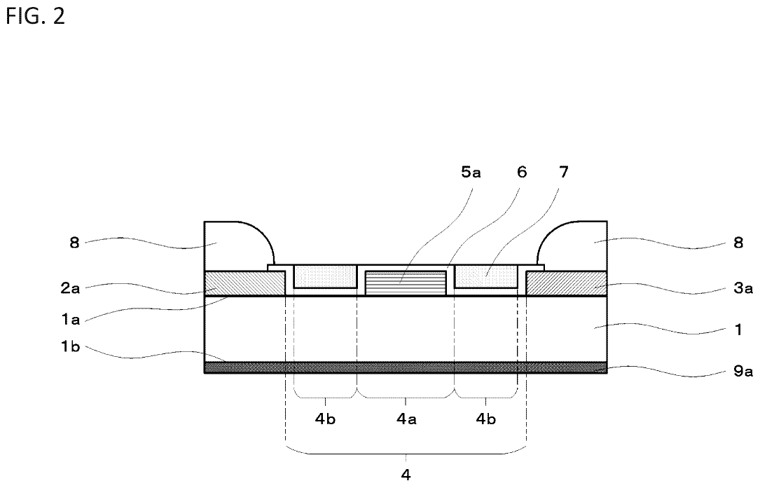

FIGS. 1 and 2 are a planar schematic diagram and a cross-sectional schematic diagram, respectively, showing the semiconductor apparatus according to the present embodiment. The semiconductor apparatus includes: an active region 10, which is a region where a main current of the semiconductor apparatus flows and a termination region 11, which is a region outside the active region; an emitter electrode 2a and a gate electrode 3a, which are spaced from each other on the surface of a semiconductor substrate 1; gate wiring 5a, which is covered with an insulating layer 6 formed in a gate wiring region 4 between the emitter electrode 2a and the gate electrode 3a; and a short-circuit prevention layer 7, which is formed between the emitter electrode 2a and the gate wiring 5a and between the gate electrode 3a and the gate wiring 5a. The semiconductor apparatus further includes a metal plating layer 8 formed on the emitter electrode 2a and the gate electrode 3a, and a collector electrode 9a formed on a reverse surface of the semiconductor substrate 1. In FIG. 1, the insulating layer 6 and the metal plating layer 8 are omitted for brevity of description.

The semiconductor substrate 1 includes a first main surface 1a, which is a front surface, and a second main surface 1b, which is a back surface, as shown in FIG. 2. On the side of the first main surface 1a or the second main surface 1b of the semiconductor substrate 1, semiconductor layers such as a drift layer, an emitter layer, a collector layer, a field stop layer, and an electric field relaxation layer are formed, but are not shown here.

For example, a substrate made of silicon can be used for the semiconductor substrate 1.

The emitter electrode 2a and the gate electrode 3a are a first surface electrode 2 and a second surface electrode 3, respectively, formed with a space between them and electrically insulated on the first main surface 1a of the active region 10 of the semiconductor substrate 1. For the emitter electrode 2a and the gate electrode 3a, for example, aluminum can be used, and an alloy material such as aluminum-silicon alloy can also be used.

The gate wiring region 4 is a region where the gate wiring 5a and the insulating layer 6 are formed on the first main surface 1a of the semiconductor substrate 1, and a protrusion 4a and recesses 4b are formed in the same region. In FIGS. 1 and 2, a region between the emitter electrode 2a and the gate electrode 3a is the gate wiring region 4. In FIG. 2, the width of the gate wiring region 4, i.e., the distance in the horizontal direction between the outer edge of the emitter electrode 2a and the outer edge of the gate electrode 3a, is, for example, about 100 μm. The width of the gate wiring region 4 may be less than or equal to 100 μm to enlarge the region where the main current of the semiconductor apparatus flows. Here, although not shown, the gate wiring 5a is also formed in the termination region 11.

As shown in FIGS. 1 and 2, the gate wiring 5a is an electroconductive layer 5 formed on the first main surface 1a between the emitter electrode 2a and the gate electrode 3a with a space from the emitter electrode 2a and the gate electrode 3a in a planar view. For the gate wiring 5a, for example, an electroconductive material such as aluminum can be used, and an alloy material such as aluminum-silicon alloy can also be used.

As shown in FIG. 2, the insulating layer 6 is formed to cover the gate wiring 5a, the first main surface 1a between the emitter electrode 2a and the gate electrode 3a, and an end portion of each of the emitter electrode 2a and the gate electrode 3a on the side close to the gate wiring 5a. Here, it is assumed that each end portion is a region that includes the side of the emitter electrode 2a or the side of the gate electrode 3a and occupies an area from the respective outer periphery to 100 μm inside the periphery on the upper surface of the emitter electrode 2a or the gate electrode 3a. The regions May be enlarged or reduced depending on the design of the semiconductor device. Thus, the protrusion 4a is formed on the gate wiring 5a on which the insulating layer 6 is stacked, and the recesses 4b are formed between the emitter electrode 2a and the gate wiring 5a and between the gate electrode 3a and the gate wiring 5a. For the insulating layer 6, a material with insulating properties such as silicon nitride can be used.

As shown in FIG. 2, the short-circuit prevention layer 7 is formed to cover the insulating layer 6 between the emitter electrode 2a and the gate wiring 5a and the insulating layer 6 between the gate electrode 3a and the gate wiring 5a. The short-circuit prevention layer 7 also fills in the recesses 4b so as to flatten the protrusion 4a and the recesses 4b. The thickness of the short-circuit prevention layer 7, which is the height from the lower end of the short-circuit prevention layer 7 to the upper end thereof, is equal to or larger than the thickness of the gate wiring 5a, which is the height from the lower end of the gate wiring 5a to the upper end thereof. In this configuration, the height of the short-circuit prevention layer 7 is larger than the height of the upper end of the protrusion 4a.

The short-circuit prevention layer 7 has insulating properties and is made of a material different from that of the insulating layer 6. For example, if silicon nitride or silicon oxide is used for the insulating layer 6, a material such as polyimide, polybenzoxazole, polytetrafluoroethylene, and siloxane can be used for the short-circuit prevention layer 7. Compared to an insulating material such as silicon nitride and silicon oxide used for the insulating layer 6, a material used for the short-circuit prevention layer 7 should have superior characteristics in chemical resistance to a plate processing solution, which will be described later, moisture resistance, heat resistance, adhesion, flowability, such as thixotropy and viscosity, which is a property that promotes flattening of the protrusion 4a and the recesses 4b. Polyimide and polybenzoxazole are suitable in terms of chemical resistance, moisture resistance, heat resistance, and flowability.

If the metal plating layer 8, to be described later, is formed without the short-circuit prevention layer 7 in the recesses 4b, it is difficult for liquid containing electroconductive substances to desorb and evaporate, so that the liquid adheres and remains at the bottoms of the recesses 4b, especially, at the corners which are in the vicinity of the bottoms and sidewall surfaces of the recesses 4b, where the surface tension is likely to occur. In some cases, the remaining substances spread to the bottoms and sidewall surfaces of the recesses 4b to form an electroconductive coating between the emitter electrode 2a and the gate electrode 3a. To cope with this, by forming the short-circuit prevention layer 7 and filling the recesses 4b, and then forming the metal plating layer 8, the adhering and remaining of the electroconductive substances at the bottoms of the recesses 4b and the formation of the electroconductive coating between the emitter electrode 2a and the gate electrode 3a can be suppressed. This prevents the emitter electrode 2a and the gate electrode 3a from being short-circuited.

The metal plating layer 8 is formed on each of the emitter electrode 2a and the gate electrode 3a to facilitate the heat dissipation therefrom. As shown in FIG. 2, with the metal plating layer 8 formed, the heat capacity on a front surface side of the semiconductor apparatus can be made larger compared to the case without the metal plating layer 8. Heat generated in the semiconductor apparatus can be dissipated from the metal plating layer 8 to an external space or an external material, or can be conducted to the metal plating layer 8, so that the short-circuit capacity in the semiconductor apparatus is improved.

For the metal plating layer 8, for example, nickel can be used, and an alloy such as nickel-phosphorus alloy and nickel-boron alloy or a stack such as nickel-gold stack and copper-gold stack can also be used. The nickel-phosphorus alloy can reduce manufacturing costs, and improve the heat dissipation properties and the short-circuit capacity of the semiconductor apparatus.

The collector electrode 9a is a reverse-surface electrode 9 and is formed on the second main surface 1b of the semiconductor substrate 1 as shown in FIG. 2 For the collector electrode 9a, for example, aluminum or titanium can be used, and a stack of aluminum, nickel, and gold, etc., can also be used.

Next, a manufacturing method for the semiconductor apparatus according to the present embodiment will be described. For the sake of brevity, the description of the manufacturing method for the semiconductor layers is omitted here. Unless otherwise specified, the order of manufacturing steps may differ from the order in the description.

In a surface electrode and electroconductive layer formation step, an electrode layer made of aluminum is formed as a plane, for example by a sputtering method, on the first main surface 1a of the semiconductor substrate 1 where the semiconductor layers are formed, and is patterned by an etching method. Then, the emitter electrode 2a, the gate electrode 3a and the gate wiring 5a are formed together with a space between them. Forming the emitter electrode 2a, the gate electrode 3a and the gate wiring 5a together allows the thicknesses of the emitter electrode 2a, the gate electrode 3a, and the gate wiring 5a to be the same, and thus the depths of the recesses 4b to be constant regardless of the position, making it easier to embed the short-circuit prevention layer 7 in the recesses 4b. It can also simplify the manufacturing process and reduce manufacturing costs. Here, the description that the thickness is the same or the depth is constant does not just mean that the thickness is exactly the same or the depth is exactly constant, but allows for variation from the maximum values of the thickness or the depth to about 10% less of them.

In an insulating layer formation step, a silicon nitride layer is formed, as the insulating layer 6, on the first main surface 1a of the semiconductor substrate 1 between the emitter electrode 2a and the gate electrode 3a as well as on the gate wiring 5a by, for example, a physical vapor deposition (PVD) method such as sputtering and vapor deposition or a chemical vapor deposition (CVD) method. Also, the upper surface except for the end portions of the emitter electrode 2a and the gate electrode 3a is exposed by photolithography and etching methods. Here, the protrusion 4a and the recesses 4b are formed in the gate wiring region 4 between the emitter electrode 2a and the gate electrode 3a.

In a short-circuit prevention layer formation step, photosensitive polyimide in liquid is applied using, for example, a dispenser or a spin coater such that the applied photosensitive polyimide covers the insulating layer 6 in the recesses 4b and is as thick as or thicker than the gate wiring 5a. Then, the photosensitive polyimide is irradiated with light, which cures the photosensitive polyimide to form the short-circuit prevention layer 7. If the photosensitive polyimide is applied to the outside of the gate wiring region 4, the photosensitive polyimide can be patterned to form the short-circuit prevention layer 7. The short-circuit prevention layer 7 may also be formed on the insulating layer 6 of the protrusion 4a. Instead, the short-circuit prevention layer 7 may be formed only on the insulating layer 6 of the recesses 4b by photolithography.

In a metal plating layer formation step following the short circuit prevention layer formation step, the nickel-gold stack, that is, the metal plating layer 8, is formed on the emitter electrode 2a and the gate electrode 3a by, for example, an electroless plating method. The emitter electrode 2a, the gate electrode 3a, and the short-circuit prevention layer 7, which are immersed in the plate processing solutions such as chemicals of degreasing solution, etching solution, conditioning solution, substituting solution, plating solution, and cleaning solution, are collectively referred to as immersion portions. Here, an example of plate processing will be described.

First, when the immersion portions are immersed in the degreasing solution, some of natural oxide layer formed on the surfaces of the immersion portions is dissolved, and organic matter adhering to the surfaces of the immersion portions is removed. Then, the surfaces of the immersion portions are cleaned with pure water, and the immersion portions are immersed in the etching solution to dissolve and remove the surface oxide layer. Since the residues produced by etching adhere to the surfaces of the immersion portions, the immersion portions are cleaned with pure water, etc., and are soaked in the conditioning solution to remove the residues. Then, low contamination oxide layers are formed on the immersion portions. If the short-circuit prevention layer 7 is not formed, the residues remaining in the recesses 4b or the protrusion 4a may form an electroconductive coating. In contrast, if the short-circuit prevention layer 7 is formed, the residues adhering to the surface of the short-circuit prevention layer 7 can be easily removed by cleaning.

Next, the surfaces of the immersion portions are immersed in a zinc substituting solution after being cleaned with pure water, etc. As a result, the oxide layer formed on the immersion portions is dissolved, the aluminum on the surfaces of the emitter electrode 2a and the gate electrode 3a is dissolved and ionized, and zinc is deposited. Then, by cleaning the surfaces of the immersion portions with pure water, etc., and immersing them in a nickel plating solution, the deposited zinc is substituted by nickel, forming a nickel plating layer. If the short-circuit prevention layer 7 is not formed, the electroconductive coating may be formed by, for example, a substitution reaction of the zinc remaining in the recesses 4b or the protrusion 4a with nickel. In contrast, if the short-circuit prevention layer 7 is formed, the residues adhering to the surface of the short-circuit prevention layer 7 can be easily removed by cleaning.

By cleaning the surfaces of the short-circuit prevention layer 7 and the nickel plating layer with pure water, etc., and plating them with gold, a gold plating layer preventing the oxidation of nickel is formed on the surface of the nickel plating layer. The above is the description of the metal plating layer formation step.

In a reverse-surface electrode formation step, an aluminum layer, that is, the collector electrode 9a, is formed as a plane on the second main surface 1b of the semiconductor substrate 1 by, for example, the sputtering method. As described above, the semiconductor apparatus according to the present embodiment is manufactured.

As described above, the short-circuit prevention layer 7 covers the insulating layer 6 between the emitter electrode 2a and the gate wiring 5a and the insulating layer 6 between the gate electrode 3a and the gate wiring 5a to fill the recesses 4b so as to flatten the protrusion 4a and the recesses 4b of the gate wiring region 4. As a result, when the metal plating layer 8 is formed, the residue of the substances contained in the plate processing solutions, such as the plating solution and the plating solution detergent, and the formation of the electroconductive coating between the emitter electrode 2a and the gate electrode 3a on the surface of the insulating layer 6 covering the gate wiring 5a, especially in the recesses 4b, can be suppressed. Thus, the semiconductor apparatus in which the emitter electrode 2a and the gate electrode 3a are prevented from short-circuiting can be provided by forming the metal plating layer 8 on each of the emitter electrode 2a and the gate electrode 3a, which are insulated from each other, on the surface of the semiconductor device.

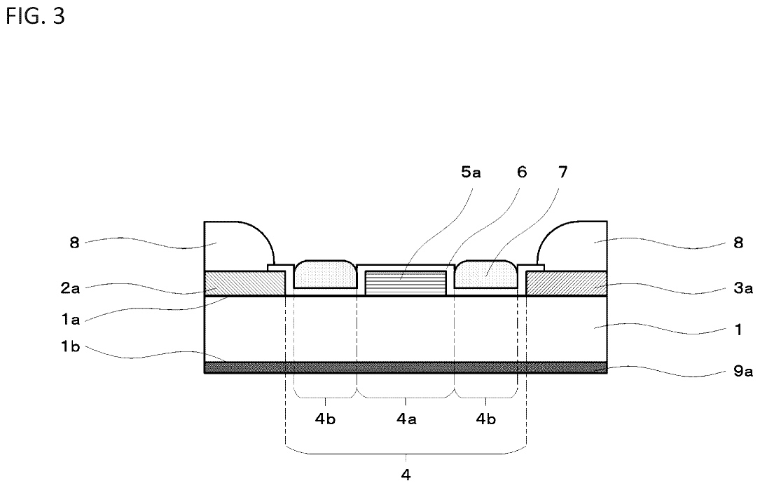

It should be noted that, as shown in FIG. 3, when the upper surface of the short-circuit prevention layer 7 is curved rather than flat, the thickness of the short-circuit prevention layer 7 need not be larger than or equal to the thickness of the gate wiring 5a at all positions, but should be larger than or equal to the thickness of the gate wiring 5a at the upper end of the curve of the upper surface of the short-circuit prevention layer 7. Here, FIG. 3 is a cross-sectional schematic diagram showing another form of the present embodiment.

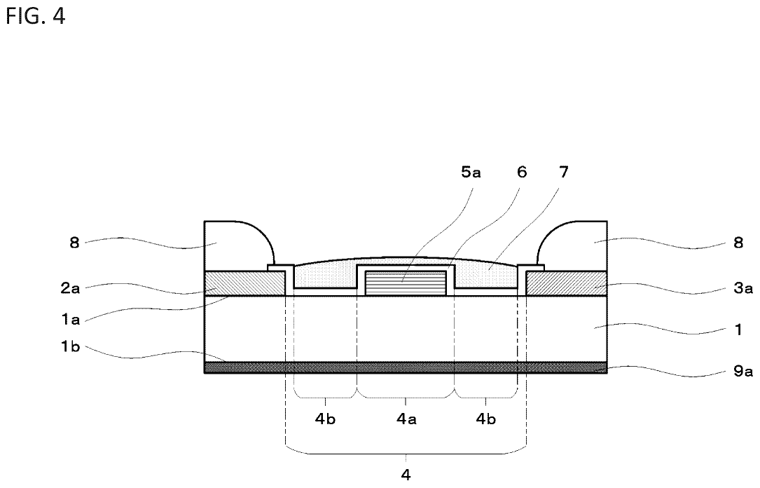

Also, as shown in the cross-sectional schematic diagram of FIG. 4, the short-circuit prevention layer 7 may be formed over the insulating layer 6 covering the gate wiring 5a, that is, over the protrusion 4a. This configuration facilitates the formation of the short-circuit prevention layer 7 while suppressing the formation of the electroconductive coating between the emitter electrode 2a and the gate electrode 3a, as described above. Here, the thickness of the short-circuit prevention layer 7 represents a height of the short-circuit prevention layer 7 from the lower end of the short-circuit prevention layer 7 formed in the recesses 4b to the upper end of the short-circuit prevention layer 7 formed on the protrusion 4a.

In addition, if the surface of the short-circuit prevention layer 7 is hydrophobic, the residue of the substances contained in the plate processing solutions, such as the plating solution and the plating solution detergent, on the surface of the short-circuit prevention layer 7 can be further suppressed when the metal plating layer 8 is formed. As a result, the formation of the electroconductive coating between the emitter electrode 2a and the gate electrode 3a, and thus the short-circuiting of the emitter electrode 2a and the gate electrode 3a, can be prevented.

As the short-circuit prevention layer formation step, an example has been described in which the short-circuit prevention layer 7 is formed using photosensitive polyimide. For example, liquid thermosetting polyimide can be used instead. In this case, the thermosetting polyimide is applied using a dispenser or a spin coater and then heated to cure, resulting in the formation of the short-circuit prevention layer 7.

### Embodiment 2

In the example of Embodiment 1, the short-circuit prevention layer 7 is formed inside the gate wiring region 4. In the present Embodiment, an example is described in which the short-circuit prevention layer 7 is formed spread outside the gate wiring region 4 so as to have regions in contact with the emitter electrode 2a and the gate electrode 3a. Other than that, the configuration is the same as for Embodiment 1.

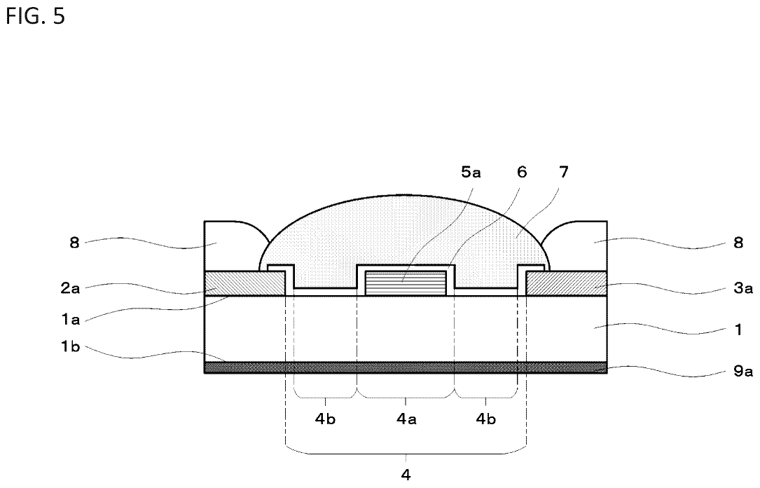

As shown in FIG. 5, the short-circuit prevention layer 7 is formed to cover the insulating layer 6 covering the end portions of the emitter electrode 2a and the gate electrode 3a so as to have regions in contact with the emitter electrode 2a and the gate electrode 3a. When the short-circuit prevention layer 7 is also formed on the emitter electrode 2a and the gate electrode 3a outside the gate wiring region 4, the formation of the short-circuit prevention layer 7 is easier than when the short-circuit prevention layer 7 is formed only within the gate wiring region 4, because the formation area is larger.

In the example shown in FIG. 5, both ends of the short-circuit prevention layer 7 have the regions in contact with the emitter electrode 2a and the gate electrode 3a, but may be formed to be located only on the insulating layer 6 covering the end portions of the emitter electrode 2a and the gate electrode 3a. In other words, both ends of the short-circuit prevention layer 7 may be formed such that there is no region in contact with the emitter electrode 2a and the gate electrode 3a.

The area of the regions where the short-circuit prevention layer 7 is in contact with the emitter electrode 2a and the gate electrode 3a, that is, the contact area, should preferably be smaller. The smaller contact area allows the metal plating layer 8 to have a larger contact area with the emitter electrode 2a and the gate electrode 3a, thereby facilitating heat dissipation through the metal plating layer 8 from the emitter electrode 2a and the gate electrode 3a.

Next, the evaluation results on the effectiveness of the short-circuit prevention and the short-circuit capacity of the semiconductor apparatus with the short-circuit prevention layer 7 will be described. Test samples, each made of a direct bonded aluminum (DBA) substrate and a semiconductor device connected by solder and wire bonding, were used for the evaluation.

In the test, a plurality of the semiconductor devices having the short-circuit prevention layer 7 also formed on the end portions of the emitter electrode 2a and the gate electrode 3a outside the gate wiring region 4 and having the metal plating layer 8 formed on the emitter electrode 2a and the gate electrode 3a were used. The metal plating layer 8 of each of the semiconductor devices had a thickness different from each other. The semiconductor substrates 1 of the semiconductor devices were each a silicon substrate. The thickness of the silicon substrate was 90 μm. The distance in the horizontal direction between the end portions of the emitter electrode 2a and the gate electrode 3a was 90 μm. The widths of the recesses 4b were 20 μm. The height of the protrusion 4a was 5 μm.

To evaluate the effectiveness of the short-circuit prevention, the electrical resistance between the emitter electrode 2a and the gate electrode 3a was measured. The electrical resistances of all test samples exceeded 30 MΩ, which is the upper limit of the instrument used for the measurement, confirming that the emitter electrode 2a and the gate electrode 3a were not short-circuited.

The test conditions for the evaluation of the short-circuit capacity were that the voltage applied to the gate electrode 3a was 20 V, the voltage applied to the capacitor used as a short circuit current source was 800 V, and the sample temperature during the test was 150 degrees C. The short-circuit capacity was defined as the maximum time of the short-circuit times at which no breakdown occurred when the duration of the short-circuit between the emitter electrode 2a and the gate electrode 3a was increased stepwise by 0.2 μs from 4.0 μs.

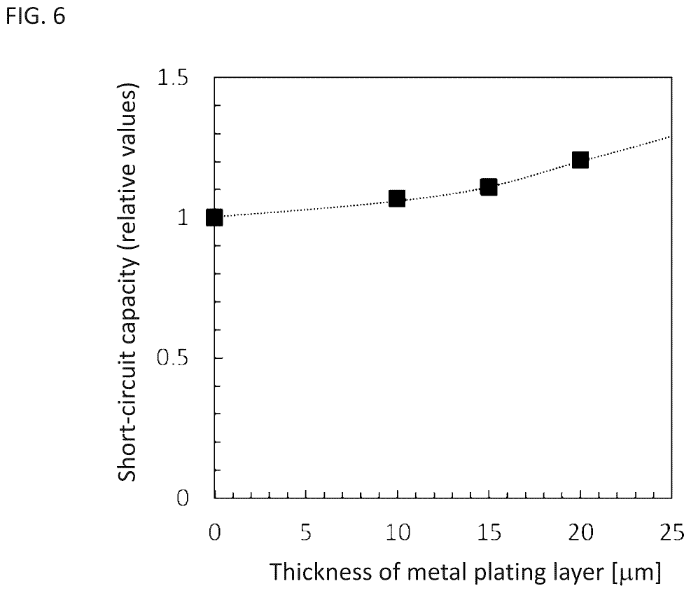

FIG. 6 is a graph showing relative values of the short-circuit capacity of the semiconductor apparatus according to the present embodiment. Here, the dotted line in FIG. 6 is an auxiliary line showing the behavior of the relative values of the short-circuit capacity with respect to each thickness. As shown in FIG. 6, it is confirmed that if it is assumed that the short-circuit capacity is 1 when the thickness of the metal plating layer 8 is 0 μm, that is, when the metal plating layer 8 is not formed, then when the metal plating layer 8 is formed, the relative values of the short-circuit capacity, which is positively correlated with the heat dissipation properties, exceed 1.

As described above, even when the short-circuit prevention layer 7 is formed on the end portions of the emitter electrode 2a and the gate electrode 3a outside the gate wiring region 4, the emitter electrode 2a and the gate electrode 3a are prevented from short-circuiting by forming the metal plating layer 8 on each of the emitter electrode 2a and the gate electrode 3a, which are insulated from each other, on the surface of the semiconductor device. In addition, the thicker metal plating layer 8 can prevent the emitter electrode 2a and the gate electrode 3a from being short-circuited and further improve the short-circuit capacity in the semiconductor apparatus.

Note that in the example shown for Embodiments 1 and 2, the first surface electrode 2, the second surface electrode 3, the electroconductive layer 5, and the reverse-surface electrode 9 are the emitter electrode 2a, the gate electrode 3a, the gate wiring 5a, and the collector electrode 9a, respectively, and an insulated gate bipolar transistor is formed in the semiconductor apparatus. Instead, they may be a source electrode, the gate electrode 3a, the gate wiring 5a, and a drain electrode, respectively, and an insulated gate field effect transistor may be formed in the semiconductor apparatus.

Meanwhile, in the gate wiring region 4 shown in FIG. 2, if the distance in the horizontal direction between the insulating layer 6 covering the emitter electrode 2a and the insulating layer 6 covering the gate wiring 5a, that is, the width of the recess 4b, is from 1 μm to 30 μm, inclusive, and also, if the height from the lower end of the gate wiring 5a to the upper end of the insulating layer 6 covering the gate wiring 5a, that is, the height of the protrusion 4a is from 0.5 μm to 10 μm, inclusive, the protrusion 4a or the recess 4b is likely to form the electroconductive coating. The recess 4b is narrow and deep in its configuration, so that liquid containing the electroconductive substances is more likely to adhere and remain, and thus the electroconductive coating is more likely to expand and form from the recess 4b to the protrusion 4a. The same is true for the distance in the horizontal direction between the insulating layer 6 covering the gate electrode 3a and the insulating layer 6 covering the gate wiring 5a. Therefore, it is even more desirable to form the short-circuit prevention layer 7 to prevent the short-circuit between the emitter electrode 2a and the gate electrode 3a.

The thickness of the emitter electrode 2a and the gate electrode 3a should be between 1 μm inclusive and 10 μm exclusive. With the emitter electrode 2a and the gate electrode 3a of the thicknesses between 1 μm inclusive and 10 μm exclusive, the time required for forming the electrodes can be suppressed and the heat dissipation properties and the short-circuit capacity of the semiconductor apparatus can be improved.

The thickness of the metal plating layer 8 should be between 1 μm inclusive and 50 μm inclusive, preferably, between 5 μm inclusive and 40 μm inclusive. With the metal plating layer 8 of the thicknesses between 5 μm inclusive and 40 μm inclusive, the time required for forming the plating layer can be suppressed and the heat dissipation properties and the short-circuit capacity of the semiconductor apparatus can be improved. The metal plating layer 8 of the thicknesses thicker than 50 μm may increase the stress on the semiconductor device and cause a defect of warping the semiconductor device.

For the semiconductor substrate 1, a substrate made of compound semiconductors such as silicon carbide, gallium nitride, gallium arsenide, or gallium oxide can also be used. A semiconductor apparatus including a substrate made of the compound semiconductors may sometimes be operated at a higher temperature than a semiconductor apparatus including a substrate made of silicon. In this respect, the semiconductor apparatus having the short-circuit prevention layer 7 and the metal plating layer 8 formed can effectively increase the heat dissipation from the metal plating layer 8 while preventing the short-circuit.

The thickness of the semiconductor substrate 1 should be between 1 μm inclusive and 150 μm inclusive, preferably between 50 μm inclusive and 100 μm inclusive, in terms of the conduction loss, the turn-off loss, the heat dissipation properties and the like of the semiconductor apparatus. The semiconductor substrate 1 with the thickness between 50 μm inclusive and 100 μm inclusive can be easily fabricated in the manufacturing process, so that cracking, breaking and other defects of the semiconductor substrate 1 can be prevented, while suppressing the conduction loss and the turn-off loss. A thin semiconductor substrate 1 with a thickness of 100 μm or less may suffer from the lower heat capacity of the semiconductor substrate 1 and the decrease of the short-circuit capacity in the semiconductor apparatus. In this case, it is further desired to prevent short-circuiting by forming the short-circuit prevention layer 7 and to improve the heat dissipation properties in the semiconductor apparatus by forming the metal plating layer 8.

With the thickness of the short-circuit prevention layer 7 equal to or at most 5 μm different from the thickness of the gate wiring 5a, the pressure applied to the semiconductor device can be distributed, for example, when the semiconductor device is pressurized from above during the mounting process. As a result, defects in the semiconductor device, such as cracking caused by excessive pressure or bonding failure caused by insufficient pressure, can be suppressed.

Meanwhile, in the above example, the reverse-surface electrode 9 only includes the collector electrode 9a, but a metal plating layer may be formed on the opposite surface of the surface of the collector electrode 9a in contact with the semiconductor substrate 1. For example, when forming the metal plating layer 8 on the emitter electrode 2a and the gate electrode 3a, which are the surface electrodes, a second metal plating layer may be formed on the collector electrode 9a at the same time. The second metal plating layer formed on the collector electrode 9a can facilitate heat dissipation from the reverse-surface side of the semiconductor apparatus.

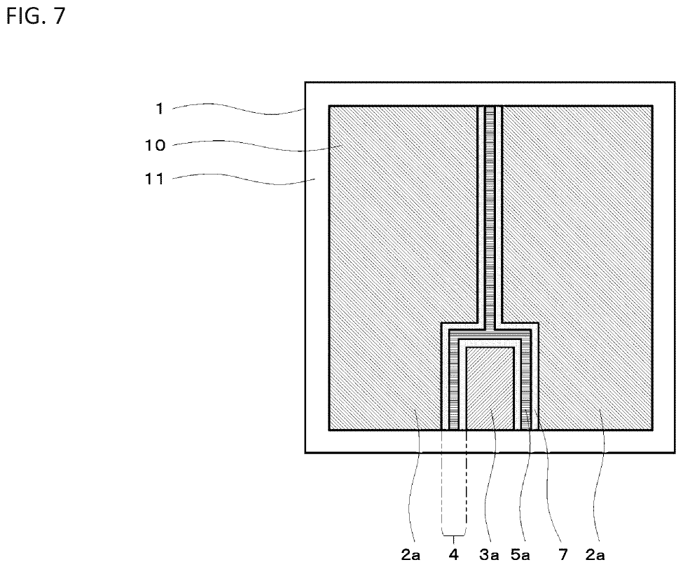

Although not shown in the figures, the gate electrode 3a and the gate wiring 5a are connected in the active region 10 or the termination region 11 via an electroconductive wiring layer, such as a polysilicon layer formed on a lower layer side than the gate electrode 3a and the gate wiring 5a. In addition to being formed between the emitter electrode 2a and the gate electrode 3a as shown in the planar schematic diagram of FIG. 7, the gate wiring 5a may also be formed on a region dividing the emitter electrode 2a in the planar view, that is, on the gate wiring region 4 between the emitter electrodes 2a.

### Embodiment 3

In the present embodiment, the semiconductor apparatus according to Embodiment 1 or 2 described above is applied to a power converter 200. Although the application of the semiconductor apparatus according to Embodiment 1 or 2 is not limited to a particular power converter, in the following description, the semiconductor apparatus according to Embodiment 1 or 2 is applied to a three-phase inverter.

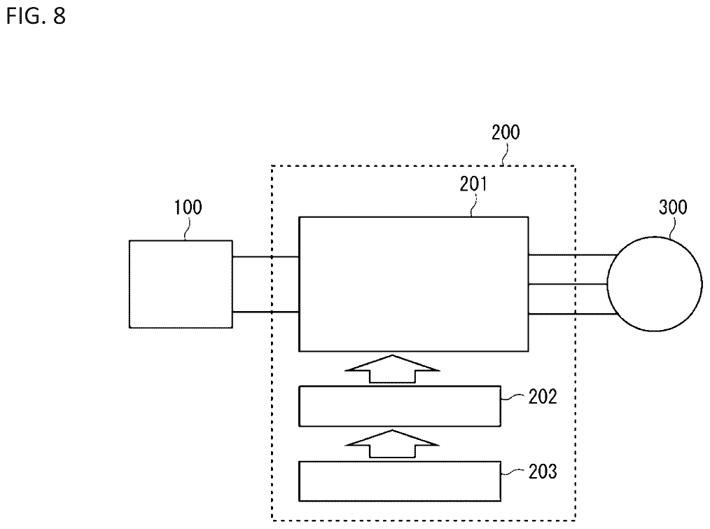

FIG. 8 is a schematic diagram showing a schematic configuration of a power conversion system to which the power converter 200 according to the present embodiment is applied. The power conversion system includes a power supply 100, the power converter 200, and a load 300.

The power supply 100 is a DC power supply to provide DC power to the power converter 200. The power supply 100 is diverse and may be configured, for example, as a DC system, a solar cell, or a storage battery, and may also be configured with a rectifier circuit or an AC/DC converter connected to an AC system. The power supply 100 may be a DC/DC converter that converts the DC power which is an output from a DC power grid to a required power.

The power converter 200 is a three-phase inverter connected between the power supply 100 and the load 300 to convert the DC power supplied from the power supply 100 to AC power and to supply the AC power to the load 300. As shown in FIG. 8, the power converter 200 includes a main conversion circuit 201 to convert inputted DC power to AC power to output the AC power, a drive circuit 202 to output a drive signal for driving each switching device of the main conversion circuit 201, and a control circuit 203 to output a control signal for controlling the drive circuit 202 to the drive circuit 202.

The load 300 is a three-phase electric motor driven by the AC power supplied by the power converter 200. The load 300 is not limited to a specific-use motor but is an electric motor installed in various electric equipment. For example, it is an electric motor for a hybrid vehicle, an electric vehicle, a railway car, an elevator, or an air conditioning system.

The details of the power converter 200 will be described below. The main conversion circuit 201, which includes a switching device and a freewheel diode (both not shown), converts the DC power supplied from the power supply 100 to AC power by the switching operation of the switching device and supplies the AC power to the load 300.

Although there is a variety of specific circuit configurations for the main conversion circuit 201, the main conversion circuit 201 according to the present embodiment is a two-level three-phase full-bridge circuit, which is composed of six switching devices and six freewheel diodes each connected in anti-parallel with its counterpart switching device. The semiconductor apparatus according to Embodiment 1 or 2 is applied to the switching devices included in the main conversion circuit 201. The six switching devices are combined into pairs. In each pair, the switching devices are connected in series to form a pair of upper and lower arms. Each pair of the upper and lower arms constitutes U-phase, V-phase, or W-phase of the full bridge circuit. The output terminals from three upper-and-lower arms, that is, the three output terminals of the main conversion circuit 201, are connected to the load 300.

The drive circuit 202 generates drive signals to drive switching devices of the main conversion circuit 201 and provides them to the control electrodes of switching devices of the main conversion circuit 201. Specifically, in accordance with the control signals received from the control circuit 203 (described later), the drive circuit outputs to the control electrode of each switching device a drive signal that makes the switching device be in its ON state or a drive signal that makes the switching device be in its OFF state. When the switching device is to be kept in its ON state, the drive signal is a signal with a voltage higher than the threshold voltage of the switching device, that is, an ON signal, whereas, when the switching device is to be kept in its OFF state, the drive signal is a signal with a voltage lower than the threshold voltage of the switching device, that is, an OFF signal.

The control circuit 203 controls the switching devices of the main conversion circuit 201 so that the needed power can be supplied to the load 300. Specifically, the time duration in which each switching device of the main conversion circuit 201 is required to be in its ON state, which is ON time, is calculated on the basis of the power to be supplied to the load 300. The main conversion circuit 201 can be controlled, for example, by the pulse width modulation control in which the ON time of the switching device is modulated according to the voltage to be outputted. The control circuit 203 outputs the control signals as control commands to the drive circuit 202 in such a way that, at each moment, an ON signal is outputted to a switching device that is required to be in its ON state and an OFF signal is outputted to a switching device that is required to be in its OFF state. In accordance with these control signals, the drive circuit 202 outputs an ON signal or an OFF signal as the drive signal to the control electrode of each of the switching devices.

The power converter 200 according to the present embodiment includes the semiconductor apparatus of Embodiment 1 or 2 as the switching devices in the main conversion circuit 201, so that the power converter 200 capable of preventing the switching devices from short-circuiting and improving the short-circuit capacity is obtained.

In the present embodiment, an example is described in which Embodiment 1 or 2 is applied to a three-phase inverter with two levels. However, not limited to this, it can be applied to various power converters. For example, the power converter may be a multilevel power converter, such as a three-level power converter. If power is supplied to a single-phase load, Embodiment 1 or 2 can be applied to a single-phase inverter. Embodiment 1 or 2 can also be applied to a DC/DC converter or an AC/DC converter when supplying power to a DC load or the like.

Not limited to application to an electric motor as a load, the power converter according to Embodiment 1 or 2 can be used, for example, as a power supply system of an electric discharge machine, a laser processing machine, an induction heating cooker, and a wireless power supply system, and also as a power conditioner of a photovoltaic power generation system and a power storage system.

In addition to the foregoing, any combination of embodiments, any variation of components in any embodiment, or any omission of components in any embodiment is possible.

### DESCRIPTION OF SYMBOLS

1 . . . semiconductor substrate,
1a . . . first main surface,
1b . . . second main surface,
2 . . . first surface electrode,
2a . . . emitter electrode,
3 . . . second surface electrode,
3a . . . gate electrode,
4 . . . gate wiring region,
4a . . . protrusion,
4b . . . recess,
5 . . . electroconductive layer,
5a . . . gate wiring,
6 . . . insulating layer,
7 . . . short-circuit prevention layer,
8 . . . metal plating layer,
9 . . . reverse-surface electrode,
9a . . . collector electrode,
10 . . . active region,
11 . . . termination region,
100 . . . power supply,
200 . . . power converter,
201 . . . main conversion circuit,
202 . . . drive circuit,
203 . . . control circuit,
300 . . . load

1. A semiconductor apparatus comprising:
a semiconductor substrate having a first main surface and a second main surface which is an opposite surface to the first main surface;
a first surface electrode formed on the first main surface;
a second surface electrode formed separately from the first surface electrode in a planar view and electrically insulated from the first surface electrode;
an electroconductive layer having an electroconductive property formed on the first main surface between the first surface electrode and the second surface electrode with a space from the first surface electrode and the second surface electrode in a planar view;
an insulating layer having an insulating property formed to cover the electroconductive layer, the first main surface between the first surface electrode and the second surface electrode, and an end portion of each of the first surface electrode and the second surface electrode on a side close to the electroconductive layer;
a short-circuit prevention layer having an insulating property formed to cover the insulating layer between the first surface electrode and the electroconductive layer and the insulating layer between the second surface electrode and the electroconductive layer, the short-circuit prevention layer having a thickness equal to or larger than a height from a lower end to an upper end of the electroconductive layer and being made of a material different from that of the insulating layer;
a metal plating layer formed on each of the first surface electrode and the second surface electrode; and
a reverse-surface electrode formed on the second main surface.

2. The semiconductor apparatus according to claim 1, wherein the short-circuit prevention layer is formed to further cover the insulating layer covering the electroconductive layer.

3. The semiconductor apparatus according to claim 1, wherein the short-circuit prevention layer is formed to further cover the insulating layer covering the end portions of the first surface electrode and the second surface electrode, and has regions in contact with the first surface electrode and the second surface electrode.

4. The semiconductor apparatus according to claim 1, wherein the short-circuit prevention layer is made of polyimide or poly benzoxazole.

5. The semiconductor apparatus according to claim 1, wherein a surface of the short-circuit prevention layer is hydrophobic.

6. The semiconductor apparatus according to claim 1, wherein a thickness of the electroconductive layer is the same as thicknesses of the first surface electrode and the second surface electrode.

7. The semiconductor apparatus according to claim 1, wherein the first surface electrode, the second surface electrode, the electroconductive layer, and the reverse-surface electrode are an emitter electrode, a gate electrode, gate wiring, and a collector electrode, respectively, and are formed into an insulated gate bipolar transistor.

8. The semiconductor apparatus according to claim 1, wherein the first surface electrode, the second surface electrode, the electroconductive layer, and the reverse-surface electrode are a source electrode, a gate electrode, gate wiring, and a drain electrode, respectively, and are formed into an insulated gate field effect transistor.

9. The semiconductor apparatus according to claim 1, wherein at least one of a horizontal distance between the insulating layer covering the first surface electrode and the insulating layer covering the electroconductive layer and a horizontal distance between the insulating layer covering the second surface electrode and the insulating layer covering the electroconductive layer is from 1 μm to 30 μm, inclusive.

10. The semiconductor apparatus according to claim 9, wherein a height from a lower end of the electroconductive layer to an upper end of the insulating layer covering the electroconductive layer is from 0.5 μm to 10 μm, inclusive.

11. The semiconductor apparatus according to claim 1, wherein the first surface electrode and the second surface electrode each have a thickness of 1 μm inclusive to 10 μm exclusive, and the metal plating layer has a thickness of 5 μm inclusive to 40 μm inclusive.

12. The semiconductor apparatus according to claim 1, wherein the semiconductor substrate is made of silicon, silicon carbide, gallium arsenide, gallium nitride, or gallium oxide and has a thickness of 50 μm inclusive to 100 μm inclusive.

13. A power converter comprising:
a main conversion circuit that includes a semiconductor apparatus according to claim 1, and converts an input power and outputs the same;
a drive circuit that outputs a drive signal for driving the semiconductor apparatus to the semiconductor apparatus; and
a control circuit that outputs a control signal for controlling the drive circuit to the drive circuit.

14. A manufacturing method for a semiconductor apparatus, comprising:
forming a first surface electrode, a second surface electrode and the electroconductive layer with a space from each other in a planar view by forming and patterning a planar electrode layer on a first main surface of a semiconductor substrate;
forming the electroconductive layer, the first main surface between the first surface electrode and the second surface electrode, and the insulating layer covering an end portion of each of the first surface electrode and the second surface electrode on a side close to the electroconductive layer using a PVD or CVD method;
forming a short-circuit prevention layer having an insulating property, the short-circuit prevention layer covering the insulating layer between the first surface electrode and the electroconductive layer and the insulating layer between the second surface electrode and the electroconductive layer, having a thickness equal to or larger than a height from a lower end to an upper end of the electroconductive layer, and being made of a material different from that of the insulating layer;
forming a metal plating layer, after the forming of the short-circuit prevention layer, on the first surface electrode and on the second surface electrode using a plating method by immersing the first surface electrode, the second surface electrode and the short-circuit prevention layer in a plate processing solution; and
forming a reverse-surface electrode on a second main surface which is an opposite surface to the first main surface of the semiconductor substrate.

15. The manufacturing method for the semiconductor apparatus according to claim 14, wherein, in the forming of the short-circuit prevention layer, the insulating layer covering the electroconductive layer is further covered by the short-circuit prevention layer.

16. The manufacturing method for the semiconductor apparatus according to claim 14, wherein, in the forming of the short-circuit prevention layer, the insulating layer covering the end portions of the first surface electrode and the second surface electrode is further covered by the short-circuit prevention layer to cause the short-circuit prevention layer to be in contact with the first surface electrode and the second surface electrode.

17. The manufacturing method for the semiconductor apparatus according to claim 14, wherein the first surface electrode, the second surface electrode, the electroconductive layer, and the reverse-surface electrode are an emitter electrode, a gate electrode, gate wiring, and a collector electrode, respectively, and are formed into an insulated gate bipolar transistor.

18. The manufacturing method for the semiconductor apparatus according to claim 14, wherein the first surface electrode, the second surface electrode, the electroconductive layer, and the reverse-surface electrode are a source electrode, a gate electrode, gate wiring, and a drain electrode, respectively, and are formed into an insulated gate field effect transistor.

19. The manufacturing method for the semiconductor apparatus according to claim 14, wherein the short-circuit prevention layer is formed by applying a liquid material using a dispenser and curing the liquid material with light or heat.
